(19) United States
(12) Patent Application Publication
(10) Pub. No.: US 2025/0112620 A1
(43) Pub. Date: Apr. 3, 2025

(54) ACOUSTIC WAVE DEVICE

(71) Applicant: Murata Manufacturing Co., Ltd., Nagaokakyo-shi (JP)

(72) Inventor: Eiji FUJIMORI, Nagaokakyo-shi (JP)

(21) Appl. No.: 18/976,439

(22) Filed: Dec. 11, 2024

Related U.S. Application Data
(63) Continuation of application No. PCT/JP2023/028741, filed on Aug. 7, 2023.

(30) Foreign Application Priority Data
Sep. 9, 2022 (JP) 2022-143523

(51) Int. Cl. H03H 9/52; H03H 9/64

(52) U.S. Cl. CPC H03H 9/52; H03H 9/6476

(57) ABSTRACT

An acoustic wave device includes a first acoustic wave filter, a first conductor portion between the first acoustic wave filter and a second acoustic wave filter and connected to a second functional conductor portion of the second acoustic wave filter. The first acoustic wave filter includes a signal electrode on a second main surface of a first piezoelectric substrate and connected to the first conductor portion, a ground electrode on the second main surface of the first piezoelectric substrate, and a second conductor portion connected to the ground electrode. The ground electrode overlaps a first functional conductor portion and does not overlap the signal electrode in a thickness direction of the first piezoelectric substrate. The second conductor portion is located between first and second main surfaces of the first piezoelectric substrate and spaced apart from the first main surface.

### CROSS REFERENCE TO RELATED APPLICATIONS

This application claims the benefit of priority to Japanese Patent Application No. 2022-143523 filed on Sep. 9, 2022 and is a Continuation Application of PCT Application No. PCT/JP2023/028741 filed on Aug. 7, 2023. The entire contents of each application are hereby incorporated herein by reference.

### BACKGROUND OF THE INVENTION

### 1. Field of the Invention

The present invention relates to acoustic wave devices, and more specifically, to acoustic wave devices each including a first acoustic wave filter and a second acoustic wave filter.

### 2. Description of the Related Art

International Publication No. 2018/235433 discloses an acoustic wave device including a first acoustic wave filter, a second acoustic wave filter, and a bump (first conductor portion) that connects the first acoustic wave filter and the second acoustic wave filter to each other.

In the acoustic wave device disclosed in International Publication No. 2018/235433, the first acoustic wave filter includes a first substrate (first piezoelectric substrate) having piezoelectricity in at least a portion thereof and a first functional electrode provided on a first surface (first main surface) of the first substrate. In addition, the second acoustic wave filter includes a second substrate (second piezoelectric substrate) having piezoelectricity in at least a portion thereof and a second functional electrode provided on a first surface (third main surface) of the second substrate. In addition, the first acoustic wave filter is provided on a second surface (second main surface) of the first substrate and further includes a signal terminal (signal electrode) electrically connected to the second functional electrode, a ground terminal (ground electrode), and an insulating film interposed between the ground terminal and the signal terminal in the thickness direction of the first substrate.

In the acoustic wave device disclosed in International Publication No. 2018/235433, a decrease in isolation characteristics between the first functional electrode and the signal electrode can be suppressed, but low profile cannot be easily achieved because the ground electrode, the insulating film, and the signal electrode are laminated on the second main surface of the first piezoelectric substrate.

### SUMMARY OF THE INVENTION

Example embodiments of the present invention provide acoustic wave devices each with improved isolation characteristics while achieving low profile.

An acoustic wave device according to an example embodiment of the present invention includes a first acoustic wave filter, a second acoustic wave filter, and a first conductor portion. The first acoustic wave filter includes a first piezoelectric substrate and a first functional conductor portion. The first piezoelectric substrate includes a first main surface and a second main surface that face away from each other. The first functional conductor portion is provided on the first main surface of the first piezoelectric substrate. The second acoustic wave filter includes a second piezoelectric substrate and a second functional conductor portion. The second functional conductor portion is provided on the second piezoelectric substrate. The second acoustic wave filter is located above the first acoustic wave filter. The first conductor portion is interposed between the first acoustic wave filter and the second acoustic wave filter. The first conductor portion is connected to the second functional conductor portion. The first acoustic wave filter includes a signal electrode, a ground electrode, and a second conductor portion. The signal electrode is provided on the second main surface of the first piezoelectric substrate. The signal electrode is connected to the first conductor portion. The ground electrode is provided on the second main surface of the first piezoelectric substrate. The second conductor portion is connected to the ground electrode. The ground electrode overlaps the first functional conductor portion and does not overlap the signal electrode in plan view in a thickness direction of the first piezoelectric substrate. The second conductor portion is located between the first main surface and the second main surface of the first piezoelectric substrate and is spaced apart from the first main surface.

In acoustic wave devices according to example embodiments of the present invention, isolation characteristics are improved and a low profile is achieved.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a cross-sectional view of a main portion of an acoustic wave device according to example embodiment 1 of the present invention.

FIG. 2 is a bottom view of the acoustic wave device according to example embodiment 1 of the present invention.

FIG. 3 is a bottom view of the acoustic wave device according to example embodiment 1 of the present invention in which a plurality of external connection terminals are not illustrated.

FIG. 4 is a transparent view of a first acoustic wave filter of the acoustic wave device according to example embodiment 1 of the present invention as viewed from the bottom surface.

FIG. 5 is a bottom view of a second acoustic wave filter of the acoustic wave device according to example embodiment 1 of the present invention.

FIG. 6 is an enlarged view of the main portion of the acoustic wave device according to example embodiment 1 of the present invention.

FIG. 7 is a cross-sectional view of another main portion of the acoustic wave device according to example embodiment 1 of the present invention.

FIG. 8 is a circuit diagram of the acoustic wave device according to example embodiment 1 of the present invention.

FIG. 9 is a cross-sectional view of a main portion of an acoustic wave device according to example embodiment 2 of the present invention.

FIG. 10 is a cross-sectional view of a main portion of an acoustic wave device according to example embodiment 3 of the present invention.

FIG. 11 is a cross-sectional view of a main portion of an acoustic wave device according to example embodiment 4 of the present invention.

FIG. 12 is a cross-sectional view of another main portion of the acoustic wave device according to example embodiment 4 of the present invention.

### DETAILED DESCRIPTION OF THE EXAMPLE EMBODIMENTS

The drawings referred to in the description of example embodiments 1 to 4 and the like are schematic and the ratio of the sizes and the ratio of the thicknesses of components in the drawings do not necessarily reflect actual dimensions. Example embodiments 1 to 4 and the like below are only some of various example embodiments of the present invention. In example embodiments 1 to 4 and the like below, as long as advantageous effects of the present invention are achieved, various modifications can be made depending on the design, and different components of different example embodiments may also be combined with each other as appropriate.

### Example Embodiment 1

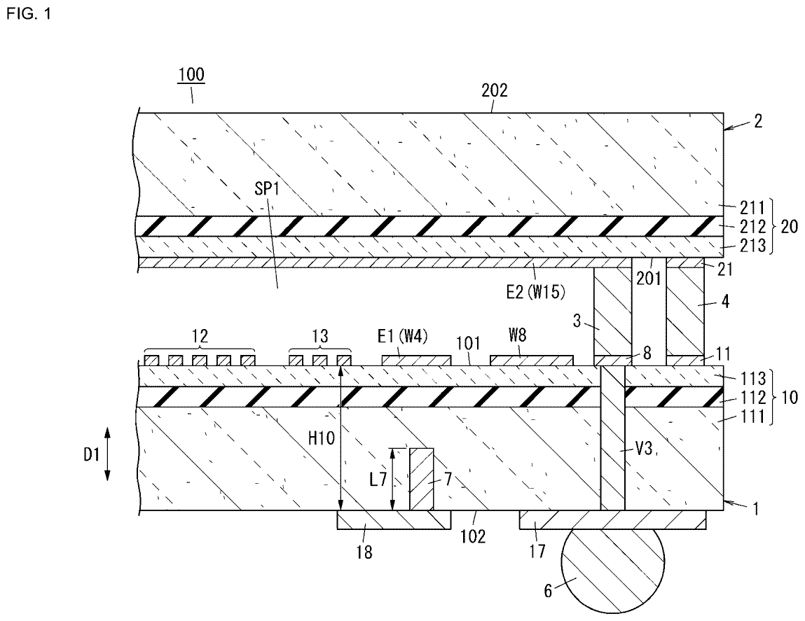

An acoustic wave device 100 according to example embodiment 1 of the present invention will be described with reference to FIGS. 1 to 8.

### (1) Summary

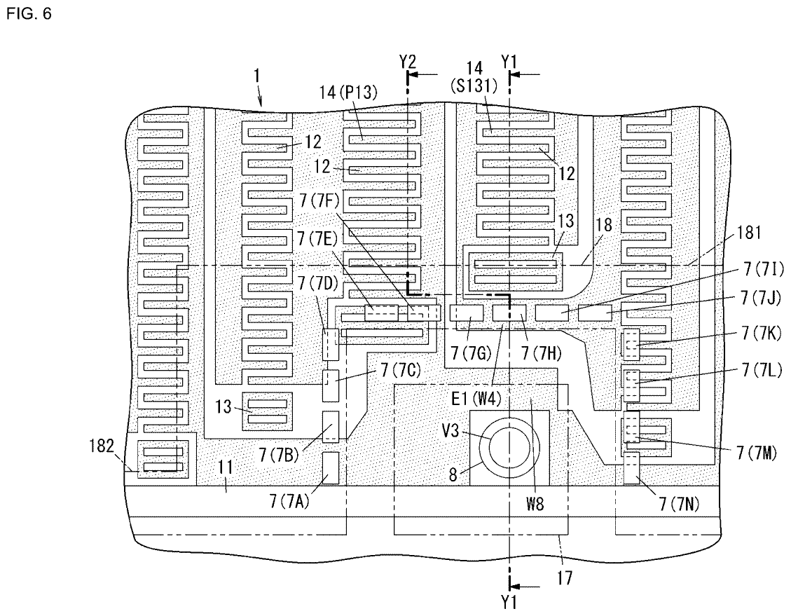

As illustrated in FIG. 1, the acoustic wave device 100 according to example embodiment 1 includes a first acoustic wave filter 1, a second acoustic wave filter 2, and a first conductor portion 3. The first acoustic wave filter 1 includes a first piezoelectric substrate 10 and a first functional conductor portion E1. The first piezoelectric substrate 10 includes a first main surface 101 and a second main surface 102 that face away from each other. The first functional conductor portion E1 is provided on the first main surface 101 of the first piezoelectric substrate 10. The first functional conductor portion E1 has a potential different from the ground potential. The second acoustic wave filter 2 includes a second piezoelectric substrate 20 and a second functional conductor portion E2. The second functional conductor portion E2 is provided on the second piezoelectric substrate 20. The second acoustic wave filter 2 is provided above the first acoustic wave filter 1. The first conductor portion is interposed between the first acoustic wave filter 1 and the second acoustic wave filter 2. The first conductor portion 3 is connected to the second functional conductor portion E2. The first acoustic wave filter 1 includes a signal electrode 17, a ground electrode 18, and a plurality of second conductor portions 7 (see FIGS. 1 and 6). The signal electrode 17 is provided on the second main surface 102 of the first piezoelectric substrate 10. The signal electrode 17 is connected to the first conductor portion 3. The ground electrode 18 is provided on the second main surface 102 of the first piezoelectric substrate 10. The ground electrode 18 has the ground potential.

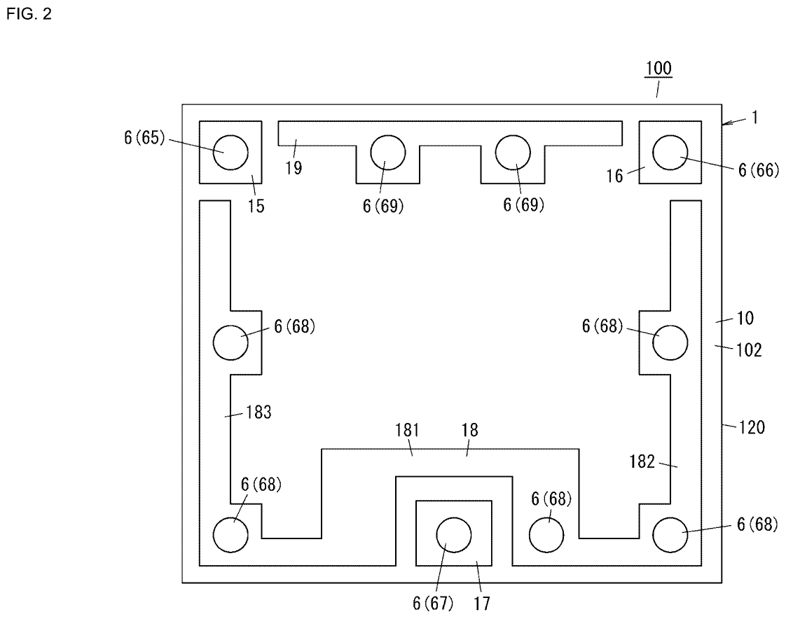

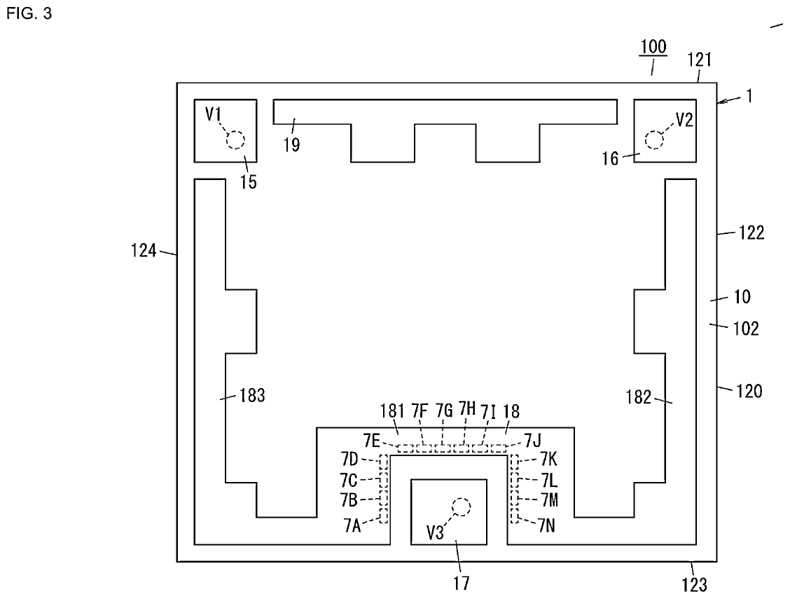

In addition, in the acoustic wave device 100, the first acoustic wave filter 1 further includes a common electrode 15, a signal electrode 16, and a ground electrode 19, as illustrated in FIGS. 2 and 3. The common electrode 15, the signal electrode 16, and the ground electrode 19 are provided on the second main surface 102 of the first piezoelectric substrate 10. In the following description, the signal electrode 16 may also be referred to as the first signal electrode 16, and the signal electrode 17 may also be referred to as the second signal electrode 17. In addition, in the following description, the ground electrode 18 may also be referred to as the first ground electrode 18, and the ground electrode 19 may also be referred to as the second ground electrode 19.

### (2) Details

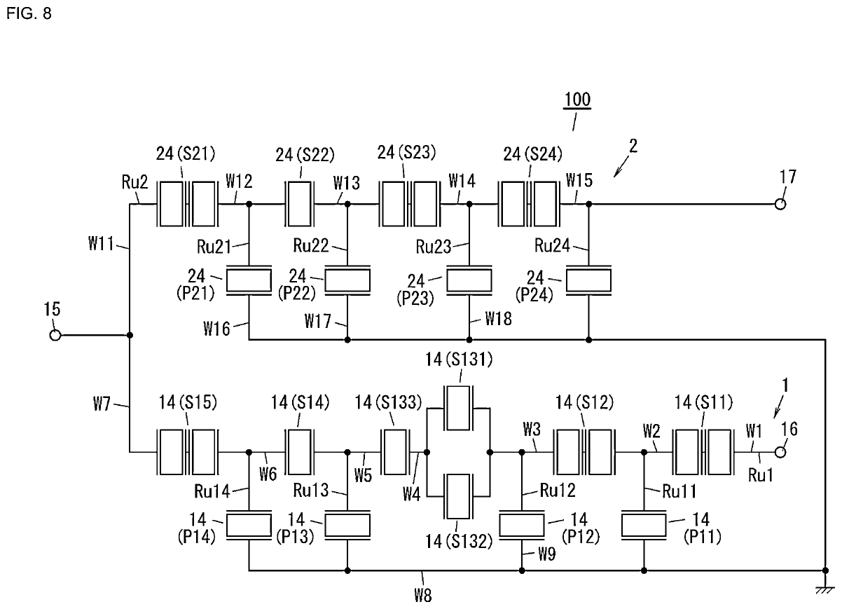

After the circuit structure of the acoustic wave device 100 is described with reference to FIG. 8, the structure of the acoustic wave device 100 will be described in more details.

### (2.1) Circuit Structure of Acoustic Wave Device

The acoustic wave device 100 is, for example, a duplexer used in a high-frequency front-end circuit of a communication device. The communication device includes an antenna. In the acoustic wave device 100, for example, the first acoustic wave filter 1 is a transmission filter, and the second acoustic wave filter 2 is a reception filter. The common electrode 15 is a signal input/output electrode common to the transmission filter and the reception filter. The pass band of the transmission filter is, for example, the transmission bandwidth of a first communication band. The first communication band is, for example, a communication band of the 3GPP (registered trademark, Third Generation Partnership Project) LTE (registered trademark, Long Term Evolution) standard. The first communication band is a communication band (for example, Band25) used for communication that supports, for example, the frequency division duplex (FDD) as a communication method but may also be a communication band used for communication that supports time division duplex (TDD). The reception filter has a pass band that is, for example, the reception band of a second communication band. The second communication band is, for example, a communication band of the 3GPP LTE standard or a communication band of the 5G NR standard. The second communication band is a communication band (for example, Band25) used for communication that supports FDD as a communication method but may also be a communication band used for communication that supports TDD. The second communication band may also be a communication band identical to the first communication band or a communication band different from the first communication band.

### (2.1.1) First Acoustic Wave Filter

As illustrated in FIG. 8, the first acoustic wave filter 1 is, for example, a ladder filter including a plurality of (for example, 11) first acoustic wave resonators 14. The plurality of first acoustic wave resonators 14 include, for example, seven series arm resonators S11, S12, S131, S132, S133, S14, and S15 and four parallel arm resonators P11, P12, P13, and P14. The seven series arm resonators S11, S12, S131, S132, S133, S14, and S15 are provided on a first signal route Ru1 (also referred to below as a series arm route Ru1) between the common electrode 15 and the first signal electrode 16. In the example in FIG. 8, each of the three series arm resonators S11, S12, and S15 of the seven series arm resonators S11, S12, S131, S132, S133, S14, and S15 includes a plurality of (two in the illustrated example) split resonators, but the structure is not limited to this example. The plurality of split resonators include one first acoustic wave resonator 14 being divided, and the split resonators are connected to each other in series without other first acoustic wave resonators 14 being interposed therebetween and without connection nodes connected to a route including other first acoustic wave resonators 14 being interposed therebetween.

Six series arm resonators S11, S12, S131, S133, S14, and S15 of the seven series arm resonators S11, S12, S131, S132, S133, S14, and S15 are connected to each other in series on the series arm route Ru1. In the first acoustic wave filter 1, on the series arm route Ru1, the series arm resonator S11, the series arm resonator S12, the series arm resonator S131, the series arm resonator S133, the series arm resonator S14, and the series arm resonator S15 are arranged in the order of the series arm resonator S11, the series arm resonator S12, the series arm resonator S131, the series arm resonator S133, the series arm resonator S14, and the series arm resonator S15 from the first signal electrode 16. In addition, in the first acoustic wave filter 1, the series arm resonator S132 is connected to the series arm resonator S131 in parallel. Accordingly, the six series arm resonators S11, S12, S132, S133, S14, and S15 of the seven series arm resonators S11, S12, S131, S132, S133, S14, and S15 are connected to each other in series.

The parallel arm resonator P11 is provided on a route Ru11 (parallel arm route Ru11) between the ground and the route between the series arm resonator S11 and the series arm resonator S12 on the series arm route Ru1. The parallel arm resonator P12 is provided on a route Ru12 (parallel arm route Ru12) between the ground and the route between the series arm resonator S12 and a parallel circuit of two series arm resonators S131 and S132 on the series arm route Ru1. The parallel arm resonator P13 is provided on a route Ru13 (parallel arm route Ru13) between the ground and the route between the series arm resonator S133 and the series arm resonator S14 on the series arm route Ru1. The parallel arm resonator P14 is provided on a route Ru14 (parallel arm route Ru14) between the ground and the route between the series arm resonator S14 and the series arm resonator S15 on the series arm route Ru1.

### (2.1.2) Second Acoustic Wave Filter

As illustrated in FIG. 8, the second acoustic wave filter 2 is, for example, a ladder filter including a plurality of (for example, eight) acoustic wave resonators 24. The plurality of second acoustic wave resonators 24 include, for example, four series arm resonators S21, S22, S23, and S24 and four parallel arm resonators P21, P22, P23, and P24. The four series arm resonators S21, S22, S23, and S24 are provided on a second signal route Ru2 (also referred to below as a series arm route Ru2) between the common electrode 15 and the second signal electrode 17. Each of the three series arm resonators, S21, S23, and S24 of the four series arm resonators S21, S22, S23, and S24 includes a plurality of (two in the illustrated example) split resonators, but the structure is not limited to this example. The plurality of split resonators include one second acoustic wave resonator 24 being divided, and the split resonators are connected to each other in series without other second acoustic wave resonators 24 being interposed therebetween and without connection nodes connected to a route including other second acoustic wave resonators 24 being interposed therebetween.

The four series arm resonators S21, S22, S23, and S24 are connected to each other in series on the series arm route Ru2. In the second acoustic wave filter 2, on the series arm route Ru2, the series arm resonator S21, the series arm resonator S22, the series arm resonator S23, and the series arm resonator S24 are arranged in the order of the series arm resonator S21, the series arm resonator S22, the series arm resonator S23, and the series arm resonator S24 from the common electrode 15.

The parallel arm resonator P21 is provided on a route Ru21 (also referred to below as a parallel arm route Ru21) between the ground and the route between the series arm resonator S21 and the series arm resonator S22 on the series arm route Ru2. The parallel arm resonator P22 is provided on a route Ru22 (also referred to below as a parallel arm route Ru22) between the ground and the route between the series arm resonator S22 and the series arm resonator S23 on the series arm route Ru2. The parallel arm resonator P23 is provided on a route Ru23 (also referred to below as a parallel arm route Ru23) between the ground and the route between the series arm resonator S23 and the series arm resonator S24 on the series arm route Ru2. The parallel arm resonator P24 is provided on a route Ru24 (also referred to below as a parallel arm route Ru24) between the ground and the route between the series arm resonator S24 and the second signal electrode 17 on the series arm route Ru2.

### (2.2) Structure of Acoustic Wave Device

The structure of the acoustic wave device 100 will be described below with reference to FIGS. 1 to 7.

As illustrated in FIG. 1, the acoustic wave device 100 includes the first acoustic wave filter 1, the second acoustic wave filter 2, and the first conductor portion 3. In addition, the acoustic wave device 100 further includes a spacer portion 4 and a plurality of external connection terminals 6 (see FIG. 2). The spacer portion 4 is interposed between the first acoustic wave filter 1 and the second acoustic wave filter 2. The spacer portion 4 has a frame shape. The acoustic wave device 100 includes a hollow space SP1 surrounded by the first acoustic wave filter 1, the second acoustic wave filter 2, and the spacer portion 4. The plurality of external connection terminals 6 are, for example, conductive bumps.

### (2.2.1) First Acoustic Wave Filter

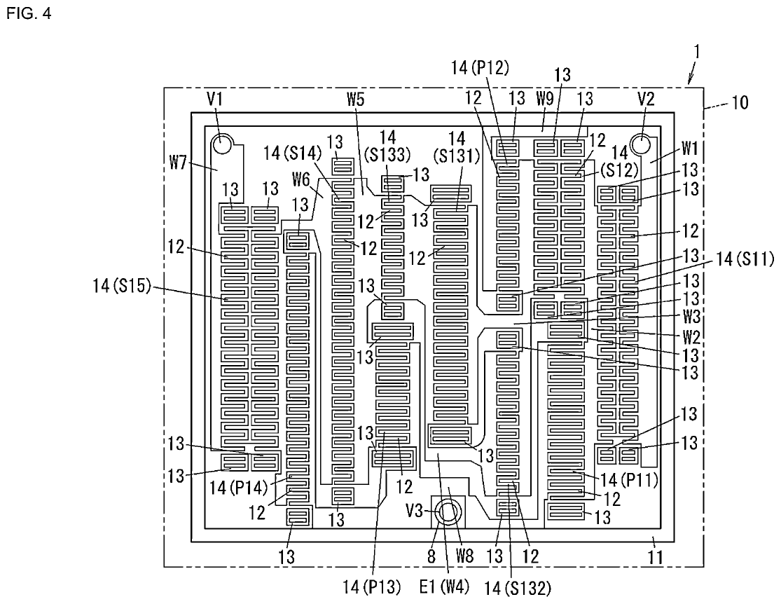

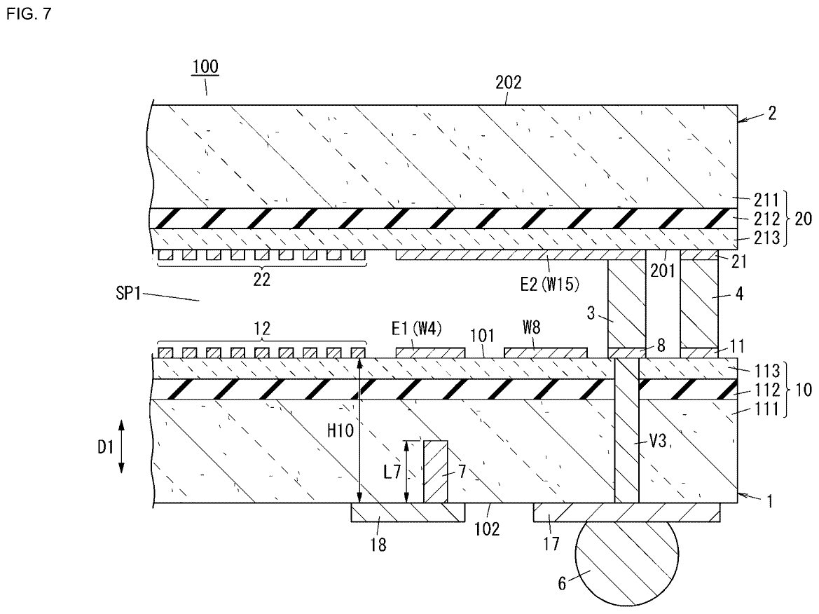

The first acoustic wave filter 1 is an acoustic wave filter that uses surface acoustic waves and includes, as illustrated in FIGS. 1 and 4, the first piezoelectric substrate 10 and the plurality of (for example, 11) first functional electrodes 12 that define a portion of each of the plurality of (for example, 11) first acoustic wave resonators 14. Each of the plurality of first functional electrodes 12 includes an IDT (interdigital transducer) electrode. Accordingly, each of the plurality of first acoustic wave resonators 14 is a surface acoustic wave (SAW) resonator. Of the seven series arm resonators S11, S12, S131, S132, S133, S14, and S15 of the plurality of first acoustic wave resonators 14, each of the three series arm resonators S11, S12, and S15 that includes a plurality of (two) split resonators includes two IDT electrodes. The two IDT electrodes are connected in series to each other by a common busbar shared therebetween. In addition, as illustrated in FIG. 4, the first acoustic wave filter 1 includes a plurality of (for example, 28) first reflectors 13. In addition, the first acoustic wave filter 1 includes a plurality of wiring conductor portions. The plurality of wiring conductor portions include a first wiring conductor portion W1, a second wiring conductor portion W2, a third wiring conductor portion W3, a fourth wiring conductor portion W4, a fifth wiring conductor portion W5, a sixth wiring conductor portion W6, a seventh wiring conductor portion W7, an eighth wiring conductor portion W8, a ninth wiring conductor portion W9, and a plurality of 10th wiring conductor portions (not illustrated). The first wiring conductor portion W1, the second wiring conductor portion W2, the third wiring conductor portion W3, the fourth wiring conductor portion W4, the fifth wiring conductor portion W5, the sixth wiring conductor portion W6, the seventh wiring conductor portion W7, the eighth wiring conductor portion W8, and the ninth wiring conductor portion W9 are connected to at least one of the plurality of first functional electrodes 12. In addition, each of the plurality of 10th wiring conductor portions is connected to at least one of the plurality of first reflectors 13. In the first acoustic wave filter 1, for example, the first functional conductor portion E1 includes the fourth wiring conductor portion W4. In addition, the first acoustic wave filter 1 further includes a through-via conductor V1 (also referred to below as a first through-via conductor V1), a through-via conductor V2 (also referred to below as a second through-via conductor V2), a through-via conductor V3 (also referred to below as a third through-via conductor V3), and a plurality of through-ground-via conductors (not illustrated). It should be noted that FIG. 1 is a cross-sectional view taken along line Y1-Y1 in FIG. 6. In FIG. 6, the first functional electrodes 12, the first reflectors 13, and the wiring conductor portions are hatched with dots. The hatching does not represent a cross section but only makes the drawing easier to see. In addition, FIG. 7 is a cross-sectional view taken along line Y1-Y2 in FIG. 6.

As illustrated in FIG. 1, the first piezoelectric substrate 10 includes the first main surface 101 and the second main surface 102 that face away from each other in a thickness direction D1 of the first piezoelectric substrate 10. In plan view in the thickness direction D1 of the first piezoelectric substrate 10, the outer edge of the first piezoelectric substrate 10 is rectangular or substantially rectangular (see, for example, FIGS. 2 to 4). A thickness H10 of the first piezoelectric substrate 10 is, for example, about 50 μm or greater and about 200 μm or smaller.

The first piezoelectric substrate 10 includes, for example, a first high-acoustic-velocity support substrate 111, a first low-acoustic-velocity film 112 provided on the first high-acoustic-velocity support substrate 111, and a first piezoelectric layer 113 provided on the first low-acoustic-velocity film 112. The first piezoelectric layer 113 has piezoelectricity. In the first high-acoustic-velocity support substrate 111, the acoustic velocity of a bulk wave propagating through the first high-acoustic-velocity support substrate 111 is higher than the acoustic velocity of an acoustic wave propagating through the first piezoelectric layer 113. Here, the bulk wave propagating through the first high-acoustic-velocity support substrate 111 is the bulk wave with the lowest acoustic velocity of a plurality of bulk waves propagating through the first high-acoustic-velocity support substrate 111. In the first low-acoustic-velocity film 112, the acoustic velocity of a bulk wave propagating through the first low-acoustic-velocity film 112 is lower than the acoustic velocity of a bulk wave propagating through the first piezoelectric layer 113.

The material of the first piezoelectric layer 113 includes, for example, lithium tantalate or lithium niobate. The thickness of the first piezoelectric layer 113 is preferably about 3.5 λ or smaller when, for example, λ is the wavelength of an acoustic wave determined by the electrode finger pitch of the IDT electrode included in the first functional electrode 12.

The material of the high-acoustic-velocity support substrate 111 includes, for example, silicon. In this case, the first high-acoustic-velocity support substrate 111 is, for example, a silicon substrate. The thickness of the silicon substrate is preferably, for example, about 10 λ or greater and about 180 μm or smaller. The resistivity of the silicon substrate is, for example, about 1 kΩcm or higher, preferably about 2 kΩcm or higher, and more preferably about 4 kΩcm or higher. The silicon substrate includes, for example, a bulk region on a side close to the first low-acoustic-velocity film 112 and a surface region on a side opposite to the first low-acoustic-velocity film 112. The surface region includes the second main surface 102 of the first piezoelectric substrate 10. The thickness of the surface region is, for example, about 1 nm or greater and about 700 nm or smaller. The bulk region is, for example, a mono-crystalline silicon layer. The mono-crystalline silicon layer is the remaining portion of a mono-crystalline silicon substrate when the surface region is provided on the mono-crystalline silicon substrate. The surface region is, for example, an amorphous silicon layer. The amorphous silicon layer is formed by, for example, degradation of a portion of the lattice structure of the mono-crystalline silicon substrate that underlies the first high-acoustic-velocity support substrate 111. The surface region is formed by, for example, injecting ions of at least one element selected from, for example, argon, silicon, oxygen, and carbon into the mono-crystalline silicon substrate. The surface region may also be formed, for example, by applying radiation to the mono-crystalline silicon substrate. The material of the first high-acoustic-velocity support substrate 111 only needs to include at least one material selected from, for example, silicon, aluminum nitride, aluminum oxide, silicon carbide, silicon nitride, sapphire, lithium tantalate, lithium niobate, quartz, alumina, zirconia, cordierite, mullite, steatite, forsterite, magnesia, and diamond.

The material of the first low-acoustic-velocity film 112 includes, for example, silicon dioxide. The material of the first low-acoustic-velocity film 112 is not limited to silicon dioxide. The material of the first low-acoustic-velocity film 112 may also be, for example, silicon dioxide, glass, silicon oxynitride, tantalum oxide, a compound formed by adding fluorine, carbon, or boron to or silicon dioxide, or a material mainly including the materials described above. The thickness of the first low-acoustic-velocity film 112 is preferably, for example, about 2 λ or smaller.

A plurality of (for example, 11) first functional electrodes 12 (see FIGS. 1 and 4) are provided on the first main surface 101 of the first piezoelectric substrate 10. As described above, each of the plurality of first functional electrodes 12 includes an IDT electrode. The plurality of first functional electrodes 12 have conductivity. The material of the plurality of first functional electrodes 12 is, for example, aluminum, copper, platinum, gold, silver, titanium, nickel, chromium, molybdenum, tungsten, tantalum, magnesium, iron, an alloy mainly including any of these metals, or the like. In addition, the plurality of first functional electrodes 12 may also have a structure in which a plurality of metal films including these metals or alloys are laminated together. In addition, for example, the plurality of first functional electrodes 12 includes a laminated film of a first metal film that includes a titanium film formed on the first main surface 101 of the first piezoelectric substrate 10 and a second metal film that includes an aluminum film formed on the first metal film. The first metal film defines and functions as a close contact film. The material of the first metal film is titanium but may also be, for example, chrome or nickel-chrome. In addition, the material of the second metal film is aluminum but may also include, for example, aluminum and copper. The thickness of the first metal film is smaller than the thickness of the second metal film. The thickness of each of the plurality of first functional electrodes 12 is, for example, about 150 nm.

In the acoustic wave device 100 according to example embodiment 1, seven first functional electrodes 12 of the plurality of first functional electrodes 12 (see FIG. 4) that correspond to the seven series arm resonators S11, S12, S131, S132, S133, S14, and S15 are conductor portions that have potentials different from the ground potential.

The plurality of (for example, 28) first reflectors 13 are provided on the first main surface 101 of the first piezoelectric substrate 10. In the acoustic wave device 100, for each of the plurality of IDT electrodes, two first reflectors 13 are provided adjacent to the IDT electrode. The two first reflectors 13 reflect acoustic waves in the acoustic wave propagation direction determined by the IDT electrode located between the two first reflectors 13. The plurality of first reflectors 13 are, for example, grating reflectors. The plurality of first reflectors 13 have conductivity. The plurality of first reflectors 13 are conductor portions that have potentials different from the ground potential or conductor portions that have the ground potential. The first reflectors 13 corresponding to the seven series arm resonators S11, S12, S131, S132, S133, S14, and S15 have potentials different from the ground potential. The material of the plurality of first reflectors 13 is the same as the material of, for example, the plurality of first functional electrodes 12. The thickness of each of the plurality of first reflectors 13 is the same as the thickness of, for example, each of the plurality of first functional electrodes 12. The thickness of each of the plurality of first reflectors 13 is, for example, about 150 nm.

The plurality of wiring conductor portions are provided on the first main surface 101 of the first piezoelectric substrate 10. As illustrated in FIG. 4, the first wiring conductor portion W1 is connected to the series arm resonator S11 and the second through-via conductor V2 and includes a portion of the first signal route Ru1 (see FIG. 8). The second wiring conductor portion W2 is connected to two series arm resonators S11 and S12 and one parallel arm resonator P11 and includes a portion of the first signal route Ru1 (see FIG. 8) and a portion of the parallel arm route Ru11 (see FIG. 8). The third wiring conductor portion W3 is connected to three series arm resonators S12, S131, and S132 and one parallel arm resonator P12 and includes a portion of the first signal route Ru1 (see FIG. 8) and a portion of the parallel arm route Ru12 (see FIG. 8). The fourth wiring conductor portion W4 is connected to three series arm resonators S131, S132, and S133, and includes a portion of the first signal route Ru1 (see FIG. 8). The fifth wiring conductor portion W5 is connected to two series arm resonators S133 and S14 and one parallel arm resonator P13 and includes a portion of the first signal route Ru1 (see FIG. 8) and a portion of the parallel arm route Ru13 (see FIG. 8). The sixth wiring conductor portion W6 is connected to two series arm resonators S14 and S15 and one parallel arm resonator P14 and includes a portion of the first signal route Ru1 (see FIG. 8) and a portion of the parallel arm route Ru14 (see FIG. 8). The seventh wiring conductor portion W7 is connected to the series arm resonator S15 and the first through-via conductor V1 and includes a portion of the first signal route Ru1 (see FIG. 8). The eighth wiring conductor portion W8 is connected to three parallel arm resonators P11, P13, and P14, and includes a portion of each of the three parallel arm routes Ru11, Ru13, and Ru14 (see FIG. 8). The ninth wiring conductor portion W9 is connected to the parallel arm resonator P12 and includes a portion of the parallel arm route Ru12 (see FIG. 8).

In addition, as illustrated in FIGS. 1 and 4, the first acoustic wave filter 1 includes a first metal portion 11 and a relay electrode 8 that are provided on the first main surface 101 of the first piezoelectric substrate 10. In plan view in the thickness direction D1 of the first piezoelectric substrate 10, the first metal portion 11 has a rectangular frame shape along the outer edge of the first piezoelectric substrate 10. In plan view in the thickness direction D1 of the first piezoelectric substrate 10, as illustrated in FIG. 4, the first metal portion 11 surrounds the plurality of first functional electrodes 12, the plurality of first reflectors 13, the plurality of wiring conductor portions, and the relay electrode 8. As illustrated in FIG. 4, the eighth wiring conductor portion W8 and the ninth wiring conductor portion W9 of the first to ninth wiring conductor portions W1 to W9 of the plurality of wiring conductor portions are connected to the first metal portion 11. Accordingly, the eighth wiring conductor portion W8 and the ninth wiring conductor portion W9 are the wiring conductor portions that have the ground potential. The relay electrode 8 has conductivity. The relay electrode 8 is a conductor portion that connects the second acoustic wave filter 2 (see FIG. 1) and the second signal electrode 17 and constitutes a portion of the second signal route Ru2 (see FIG. 8). As illustrated in FIG. 4, in plan view in the thickness direction D1 of the first piezoelectric substrate 10, the relay electrode 8 is surrounded by the first metal portion 11 and the eighth wiring conductor portion W8. The relay electrode 8 is spaced apart from the first metal portion 11 and the eighth wiring conductor portion W8 and is electrically insulated from the first metal portion 11 and the eighth wiring conductor portion W8. The first metal portion 11 and the eighth wiring conductor portion W8 are the conductor portions that have the ground potential.

In addition, the first through-via conductor V1, the second through-via conductor V2, the third through-via conductor V3, and the plurality of through-ground-via conductors pass through the first piezoelectric substrate 10 in the thickness direction D1 of the first piezoelectric substrate 10. The first through-via conductor V1, the second through-via conductor V2, the third through-via conductor V3, and the plurality of through-ground-via conductors are, for example, cylindrical or substantially cylindrical. In plan view in the thickness direction D1 of the first piezoelectric substrate 10, the first through-via conductor V1, the second through-via conductor V2, the third through-via conductor V3, and the plurality of through-ground-via conductors are, for example, circular or substantially circular. In plan view in the thickness direction D1 of the first piezoelectric substrate 10, the first through-via conductor V1, the second through-via conductor V2, the third through-via conductor V3, and the plurality of through-ground-via conductors are provided inside the first metal portion 11 having a rectangular or substantially rectangular frame shape. In plan view in the thickness direction D1 of the first piezoelectric substrate 10, the first through-via conductor V1, the second through-via conductor V2, and the third through-via conductor V3 are spaced apart from each other in the direction along the inner peripheral edge of the first metal portion 11.

In plan view in the thickness direction D1 of the first piezoelectric substrate 10, the first through-via conductor V1 overlaps the common electrode 15, as illustrated in FIG. 3. More specifically, in plan view in the thickness direction D1 of the first piezoelectric substrate 10, the entire first through-via conductor V1 overlaps a portion of the common electrode 15. The first through-via conductor V1 is in contact with the common electrode 15 and is electrically connected to the common electrode 15. In addition, in plan view in the thickness direction D1 of the first piezoelectric substrate 10, the first through-via conductor V1 overlaps a portion of the seventh wiring conductor portion W7, as illustrated in FIG. 4. The first through-via conductor V1 is in contact with the seventh wiring conductor portion W7 and is electrically connected to the seventh wiring conductor portion W7.

In addition, in plan view in the thickness direction D1 of the first piezoelectric substrate 10, the second through-via conductor V2 overlaps the first signal electrode 16, as illustrated in FIG. 3. More specifically, in plan view in the thickness direction D1 of the first piezoelectric substrate 10, the entire or substantially the entire second through-via conductor V2 overlaps a portion of the first signal electrode 16. The through-via conductor V2 is in contact with the first signal electrode 16 and is electrically connected to the first signal electrode 16. In addition, in plan view in the thickness direction D1 of the first piezoelectric substrate 10, the second through-via conductor V2 overlaps a portion of the first wiring conductor portion W1, as illustrated in FIG. 4. The second through-via conductor V2 is in contact with the first wiring conductor portion W1 and is electrically connected to the first wiring conductor portion W1.

In addition, in plan view in the thickness direction D1 of the first piezoelectric substrate 10, the third through-via conductor V3 overlaps the second signal electrode 17, as illustrated in FIG. 3. More specifically, in plan view in the thickness direction D1 of the first piezoelectric substrate 10, the entire third through-via conductor V3 overlaps a portion of the second signal electrode 17. The third through-via conductor V3 is in contact with the second signal electrode 17 and is electrically connected to the second signal electrode 17. In addition, in plan view in the thickness direction D1 of the first piezoelectric substrate 10, the third through-via conductor V3 overlaps a portion of the relay electrode 8, as illustrated in FIG. 4. The third through-via conductor V3 is in contact with the relay electrode 8 and is electrically connected to the relay electrode 8.

In plan view in the thickness direction D1 of the first piezoelectric substrate 10, the plurality of through-ground-via conductors are connected to, for example, the first ground electrode 18 or the second ground electrode 19.

In the first acoustic wave filter 1, as illustrated in FIGS. 2 and 3, the common electrode 15, the first signal electrode 16, the second signal electrode 17, the first ground electrode 18, and the second ground electrode 19 are provided on the second main surface 102 of the first piezoelectric substrate 10. The common electrode 15, the first signal electrode 16, the second signal electrode 17, the first ground electrode 18, and the second ground electrode 19 have conductivity. The first ground electrode 18 and the second ground electrode 19 have the ground potential by being electrically connected to, for example, the ground electrode of a circuit board of the communication device. The materials of the common electrode 15, the first signal electrode 16, the second signal electrode 17, the first ground electrode 18, and the second ground electrode 19 include, for example, copper. The common electrode 15, the first signal electrode 16, the second signal electrode 17, the first ground electrode 18, and the second ground electrode 19 have structures in which a plurality of metal films made of a metal or an alloy are laminated together but may also be a metal film made of a metal or an alloy instead of the plurality of metal films. The thicknesses of the common electrode 15, the first signal electrode 16, the second signal electrode 17, the first ground electrode 18, and the second ground electrode 19 are identical to each other. The metal film farthest from the second main surface 102 is, for example, a plating film formed by wet plating.

As illustrated in FIGS. 2 and 3, the common electrode 15, the first signal electrode 16, the second signal electrode 17, the first ground electrode 18, and the second ground electrode 19 are spaced apart from each other on the second main surface 102 of the first piezoelectric substrate 10. In plan view in the thickness direction D1 of the first piezoelectric substrate 10, the common electrode 15, the first signal electrode 16, the second signal electrode 17, the first ground electrode 18, and the second ground electrode 19 are spaced apart from each other. The thicknesses of the common electrode 15, the first signal electrode 16, the second signal electrode 17, the first ground electrode 18, and the second ground electrode 19 are the same or substantially the same as each other. The thickness of the common electrode 15, the first signal electrode 16, the second signal electrode 17, the first ground electrode 18, and the second ground electrode 19 is greater than the thicknesses of each of the first functional electrodes 12 and the thickness of each of the first reflectors 13.

In plan view in the thickness direction D1 of the first piezoelectric substrate 10, the common electrode 15, the first signal electrode 16, and the second signal electrode 17 are, for example, rectangular or substantially rectangular, as illustrated in FIG. 3. An outer edge 120 of the second main surface 102 of the first piezoelectric substrate 10 is rectangular or substantially rectangular and includes a first side 121, a second side 122, a third side 123, and a fourth side 124. The first side 121, the second side 122, the third side 123, and the fourth side 124 are arranged in the order of the first side 121, the second side 122, the third side 123, and the fourth side 124 in a direction along the outer edge 120 of the second main surface 102. The common electrode 15 is provided at a corner portion near the intersection between the first side 121 and the fourth side 124 of the second main surface 102 of the first piezoelectric substrate 10. The first signal electrode 16 is provided at a corner portion near the intersection between the first side 121 and the second side 122 of the second main surface 102 of the first piezoelectric substrate 10. The second signal electrode 17 is provided near the midpoint of the third side 123 of the second main surface 102 of the first piezoelectric substrate 10.

As illustrated in FIGS. 1 and 6, the first ground electrode 18 overlaps the first functional conductor portion E1 and does not overlap the second signal electrode 17 in plan view in the thickness direction D1 of the first piezoelectric substrate 10. As illustrated in FIG. 2, the first ground electrode 18 includes a first ground portion 181, a second ground portion 182, and a third ground portion 183. As illustrated in FIG. 6, in plan view in the thickness direction D1 of the first piezoelectric substrate 10, the first gland portion 181 overlaps the first functional conductor portion E1 and surrounds the second signal electrode 17. In plan view in the thickness direction D1 of the first piezoelectric substrate 10, the first ground portion 181 has a U-shape that is open toward, for example, the third side 123 (see FIG. 3) of the second main surface 102 of the first piezoelectric substrate 10, and the first ground portion 181 surrounds a portion of the second signal electrode 17 located inside the first metal portion 11. In plan view in the thickness direction D1 of the first piezoelectric substrate 10, the first ground portion 181 may also surround the entire or substantially the entire circumference of the second signal electrode 17, but the first ground portion 181 only needs to surround a portion of the second signal electrode 17 located inside the spacer portion 4 and does not necessarily need to surround the entire or substantially the entire circumference of the second signal electrode 17. As illustrated in FIGS. 2 and 3, the second ground portion 182 is connected to the first ground portion 181 and is provided along the third side 123 and the second side 122 of the second main surface 102. The third ground portion 183 is connected to the first ground portion 181 and is provided along the third side 123 and the fourth side 124 of the second main surface 102.

In plan view in the thickness direction D1 of the first piezoelectric substrate 10, the area of the first ground electrode 18 is greater than the areas of the common electrode 15, the first signal electrode 16, and the second signal electrode 17. In addition, in plan view in the thickness direction D1 of the first piezoelectric substrate 10, the area of the second ground electrode 19 is greater than the areas of the common electrode 15, the first signal electrode 16, and the second signal electrode 17. In plan view in the thickness direction D1 of the first piezoelectric substrate 10, the area of the first ground electrode 18 is greater than the area of the second ground electrode 19. In plan view in the thickness direction D1 of the first piezoelectric substrate 10, the common electrode 15, the first signal electrode 16, and the second signal electrode 17 are rectangular or substantially rectangular but may also be, for example, circular or substantially circular.

The plurality of (for example, 14) second conductor portions 7 (see FIGS. 1 and 6) are provided between the first main surface 101 and the second main surface 102 of the first piezoelectric substrate 10. In plan view in the thickness direction D1 of the first piezoelectric substrate 10, the plurality of second conductor portions 7 are, for example, rectangular or substantially rectangular. In plan view in the thickness direction D1 of the first piezoelectric substrate 10, the plurality of second conductor portions 7 overlap the first ground electrode 18. The plurality of second conductor portions 7 are connected to the first ground electrode 18. More specifically, the plurality of second conductor portions 2 are in contact with the first ground electrode 18 and are electrically connected to the first ground electrode 18. The plurality of second conductor portions 7 may be or need not be integrated with the first ground electrode 18. When the plurality of second conductor portions 7 are integrated with the first ground electrode 18, the second conductor portions 7 are made of the same material as the first ground electrode. When the second conductor portions 7 are not integrated with the first ground electrode 18, the second conductor portions 7 are made of a material different from, for example, that of the ground electrode. In addition, the plurality of second conductor portions 7 are spaced apart from the first main surface 101 of the first piezoelectric substrate 10. In other words, the plurality of second conductor portions 7 do not extend to the first main surface 101 of the first piezoelectric substrate 10. In addition, the plurality of second conductor portions 7 are spaced apart from the first functional conductor portion E1. In plan view in the thickness direction D1 of the first piezoelectric substrate 10, the plurality of second conductor portions 7 are provided so as to, for example, surround the second signal electrode 17. As illustrated in FIG. 1, the plurality of second conductor portions 7 are provided so as to reduce or prevent capacitive coupling between the first functional conductor portion E1 of the first acoustic wave filter 1 provided on the first main surface 101 of the first piezoelectric substrate 10 and the second signal electrode 17 provided on the second main surface 102 of the first piezoelectric substrate 10 and connected to the second functional conductor portion E2 of the second acoustic wave filter 2. More specifically, in plan view in the thickness direction D1 of the first piezoelectric substrate 10, at least one of the plurality of second conductor portions 7 is provided so as to overlap the first functional conductor portion E1. When the plurality of (14) second conductor portions 7 are referred to as second conductor portions 7A to 7N (see FIG. 6) to distinguish therebetween, seven second conductor portions 7G to 7M overlap the first functional conductor portion E1 (fourth wiring conductor portion W4) in plan view in the thickness direction D1 of the first piezoelectric substrate 10. The first acoustic wave filter 1 does not necessarily need to include the plurality of second conductor portions 7 and only needs to include only at least one second conductor portion 7. In addition, the first acoustic wave filter 1 may also include one second conductor portion 7 surrounding the second signal electrode 17, instead of the plurality of second conductor portions 7.

The upper limit of the length L7 (see FIG. 1) of the second conductor portions 7 in the thickness direction Dl of the first piezoelectric substrate 10 is equal to or smaller than the thickness of the first high-acoustic-velocity support substrate 111, for example, about 80% or less than the thickness H10 (see FIG. 1) of the first piezoelectric substrate 10 in terms of the reduction or prevention of leakage of a high-frequency signal from the first functional conductor portion E1 to the second conductor portions 7 and the reduction or prevention of a reduction in the manufacturing yield of the acoustic wave device 100. The length L7 of the second conductor portions 7 is, for example, about 80% or less than the thickness H10 of the first piezoelectric substrate 10, preferably about 70% or less, and more preferably about 40% or more and about 60% or less. In addition, the lower limit of the length L7 of the second conductor portions 7 is, for example, about 10% or more than the thickness H10 of the first piezoelectric substrate 10, preferably about 30% or more, and more preferably about 40% or more. In addition, the length L7 of the second conductor portions 7 may also be the same or substantially the same as the thickness of the first high-acoustic-velocity support substrate 111. In this case, since the first low-acoustic-velocity film 112 can be used as an etching stopper when a recessed portion is provided in the region in which the second conductor portions 7 are to be provided by an etching technology from the second main surface 102 of the first piezoelectric substrate 10 during manufacturing, the accuracy of the length L7 of the second conductor portions 7 can be improved.

The plurality of external connection terminals 6 (see FIGS. 1 and 2) are, for example, ball-shaped conductive bumps. The material of the conductive bumps includes, for example, solder, copper, or gold. As illustrated in FIG. 2, in plan view in the thickness direction D1 of the first piezoelectric substrate 10, the plurality of external connection terminals 6 are arranged in the direction along the outer edge 120 of the second main surface 102 of the first piezoelectric substrate 10. The plurality of external connection terminals 6 include a common terminal 65 connected to the common electrode 15, a first signal terminal 66 connected to the first signal electrode 16, a second signal terminal 67 connected to the second signal electrode 17, a plurality of first ground terminals 68 connected to the first ground electrode 18, and a plurality of second ground terminals 69 connected to the second ground electrode 19.

### (2.2.2) Second Acoustic Wave Filter

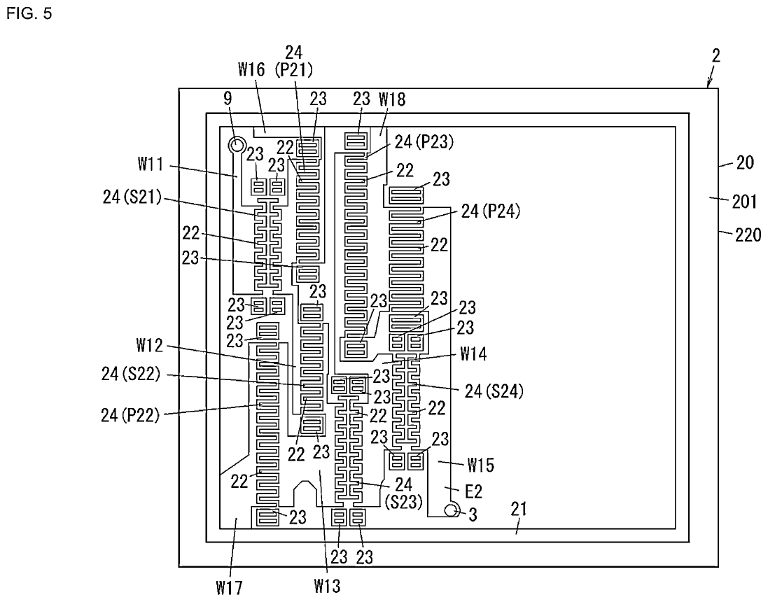

The second acoustic wave filter 2 is an acoustic wave filter that uses surface acoustic waves and includes, as illustrated in FIGS. 1 and 5, the second piezoelectric substrate 20 and a plurality of (for example, eight) second functional electrodes 22 that constitute a portion of each of the plurality of (for example, eight) second acoustic wave resonators 24. Each of the plurality of second functional electrodes 22 includes an IDT electrode. Accordingly, each of the plurality of second acoustic wave resonators 24 is a SAW resonator. Of the four series arm resonators S21, S22, S23, and S24 of the plurality of second acoustic wave resonators 24, each of the three series arm resonators S21, S23, and S24 that includes a plurality of (two) split resonators includes two IDT electrodes. The two IDT electrodes are connected in series to each other by a common busbar shared therebetween. In addition, as illustrated in FIG. 5, the second acoustic wave filter 2 includes a plurality of (for example, 22) second reflectors 23. In addition, the second acoustic wave filter 2 includes a plurality of wiring conductor portions. The plurality of wiring conductor portions include an 11th wiring conductor portion W11, a 12th wiring conductor portion W12, a 13th wiring conductor portion W13, a 14th wiring conductor portion W14, a 15th wiring conductor portion W15, a 16th wiring conductor portion W16, a 17th wiring conductor portion W17, an 18th wiring conductor portion W18, and a plurality of 19th wiring conductor portions (not illustrated). The 11th wiring conductor portion W11, the 12th wiring conductor portion W12, the 13th wiring conductor portion W13, the 14th wiring conductor portion W14, the 15th wiring conductor portion W15, the 16th wiring conductor portion W16, the 17th wiring conductor portion W17, and the 18th wiring conductor portion W18 are connected to at least one of the plurality of second functional electrodes 22. In addition, the plurality of 19th wiring conductor portions are connected to at least one of the plurality of second reflectors 23. In the second acoustic wave filter 2, for example, the second functional conductor portion E2 includes the 15th wiring conductor portion W15.

As illustrated in FIG. 1, the second piezoelectric substrate 20 has the third main surface 201 and the fourth main surface 202 that face away from each other in the thickness direction D1 of the first piezoelectric substrate 10. The third main surface 201 of the second piezoelectric substrate 20 faces the first main surface 101 of the first piezoelectric substrate 10. The second functional conductor portion E2 is provided on the third main surface 201 of the second piezoelectric substrate 20. In plan view in the thickness direction D1 of the first piezoelectric substrate 10, an outer edge 220 (see FIG. 5) of the second piezoelectric substrate 20 is rectangular or substantially rectangular.

The second piezoelectric substrate 20 includes, for example, a second high-acoustic-velocity support substrate 211, a second low-acoustic-velocity film 212 provided on the second high-acoustic-velocity support substrate 211, and a second piezoelectric layer 213 provided on the second low-acoustic-velocity film 212. The second piezoelectric layer 213 has piezoelectricity. In the second high-acoustic-velocity support substrate 211, the acoustic velocity of a bulk wave propagating through the second high-acoustic-velocity support substrate 211 is higher than the acoustic velocity of an acoustic wave propagating through the second piezoelectric layer 213. Here, the bulk wave propagating through the second high-acoustic-velocity support substrate 211 the bulk wave with the lowest acoustic velocity of a plurality of bulk waves propagating through the second high-acoustic-velocity support substrate 211. In the second low-acoustic-velocity film 212, the acoustic velocity of a bulk wave propagating through the second low-acoustic-velocity film 212 is lower than the acoustic velocity of a bulk wave propagating through the second piezoelectric layer 213.

The material of the second piezoelectric layer 213 includes, for example, lithium tantalate or lithium niobate.

The material of the second high-acoustic-velocity support substrate 211 includes, for example, silicon. In this case, the second high-acoustic-velocity support substrate 211 is a silicon substrate. The thickness for the silicon substrate is preferably, for example, about 10) or greater and about 180 μm or smaller. The resistivity of the silicon substrate is, for example, about 1 kΩcm or higher, preferably about 2 kΩcm or higher, and more preferably about 4 kΩcm or higher. The material of the second high-acoustic-velocity support substrate 211 only needs to include, for example, at least one of silicon, aluminum nitride, aluminum oxide, silicon carbide, silicon nitride, sapphire, lithium tantalate, lithium niobate, quartz, alumina, zirconia, cordierite, mullite, steatite, forsterite, magnesia, and diamond.

The material of the second low-acoustic-velocity film 212 includes, for example, silicon dioxide. The material of the second low-acoustic-velocity film 212 is not limited to silicon dioxide. The material of the second low-acoustic-velocity film 212 may also be, for example, silicon dioxide, glass, silicon oxynitride, tantalum oxide, a compound of silicon dioxide with fluorine, carbon, or boron, or a material mainly including the materials described above.

As illustrated in FIG. 5, the plurality of (for example, eight) second functional electrodes 22 are provided on the third main surface 201 of the second piezoelectric substrate 20. As described above, each of the plurality of second functional electrodes 22 includes an IDT electrode. The plurality of second functional electrodes 22 have conductivity. The material of the plurality of second functional electrodes 22 is, for example, aluminum, copper, platinum, gold, silver, titanium, nickel, chromium, molybdenum, tungsten, tantalum, magnesium, iron, or an alloy mainly including any of these metals. In addition, the plurality of second functional electrodes 22 may also have a structure in which a plurality of metal films made of these metals or alloys of the metals are laminated together. In addition, the plurality of second functional electrodes 22 include a laminated film including the first metal film including, for example, a titanium film provided on the third main surface 201 of the second piezoelectric substrate 20 and the second metal film including an aluminum film provided on the first metal film. The first metal film defines and functions as a close contact film. The material of the first metal film is titanium but may also be, for example, chrome or nickel-chrome. In addition, the material of the second metal film is aluminum but may also include, for example, aluminum and copper. The thickness of the first metal film is smaller than the thickness of the second metal film. The thickness of each of the plurality of second functional electrodes 22 is, for example, about 150 nm.

In the acoustic wave device 100 according to example embodiment 1, four second functional electrodes 22 of the plurality of second functional electrodes 22 that correspond to four series arm resonators S21, S22, S23, and S24 are conductor portions that have potentials different from the ground potential.

As illustrated in FIG. 5, the plurality of (for example, 22) second reflectors 23 are provided on the third main surface 201 of the second piezoelectric substrate 20. In the acoustic wave device 100, two second reflectors 23 are provided adjacent to the IDT electrode contained in each of the plurality of second functional electrodes 22. The two second reflectors 23 reflect an acoustic wave in the acoustic wave propagation direction determined by the IDT electrode located between the two second reflectors 23. The plurality of second reflectors 23 are, for example, grating reflectors. The plurality of second reflectors 23 have conductivity. The plurality of second reflectors 23 are conductor portions that have potentials different from the ground potential or conductor portions that have the ground potential. The second reflectors 23 corresponding to the four series arm resonators S21, S22, S23, and S24 have potentials different from the ground potential. The material of the plurality of second reflectors 23 is the same as the material of, for example, the plurality of second functional electrodes 22. The thickness of each of the plurality of second reflectors 23 is the same or substantially the same as the thickness of, for example, each of the plurality of second functional electrodes 22. The thickness of each of the plurality of second reflectors 23 is, for example, about 150 nm.

The plurality of wiring conductor portions are provided on the third main surface 201 of the second piezoelectric substrate 20. As illustrated in FIG. 5, the 11th wiring conductor portion W11 is connected to the series arm resonator S21 and the third conductor portion 9 and includes a portion of the second signal route Ru2 (see FIG. 8). The third conductor portion 9 is electrically connected to the common electrode 15 (see FIGS. 3 and 4) via the first through-via conductor V1 (see FIGS. 3 and 4). The 12th wiring conductor portion W12 is connected to two series arm resonators S21 and S22 and one parallel arm resonator P21 and includes a portion of the second signal route Ru2 (see FIG. 8) and a portion of the parallel arm route Ru21 (see FIG. 8). The 13th wiring conductor portion W13 is connected to two series arm resonators S22 and S23 and one parallel arm resonator P22 and includes a portion of the second signal route Ru2 (see FIG. 8) and a portion of the parallel arm route Ru22 (see FIG. 8). The 14th wiring conductor portion W14 is connected to two series arm resonators S23 and S24 and one parallel arm resonator P23 and includes a portion of the second signal route Ru2 (see FIG. 8) and a portion of the parallel arm route Ru23 (see FIG. 8). The 15th wiring conductor portion W15 is connected to the series arm resonator S24, the parallel arm resonator P24, and the first conductor portion 3 and includes a portion of the second signal route Ru2 (see FIG. 8) and a portion of the parallel arm route Ru24 (see FIG. 8). The 16th wiring conductor portion W16 is connected to the parallel arm resonator P21 and includes a portion of the parallel arm route Ru21 (see FIG. 8). The 17th wiring conductor portion W17 is connected to the parallel arm resonator P22 and includes a portion of the parallel arm route Ru22 (see FIG. 8). The 18th wiring conductor portion W18 is connected to two parallel arm resonators P23 and P24 and includes a portion of each of the parallel arm route Ru23 and the parallel arm route Ru24 (see FIG. 8).

In addition, as illustrated in FIGS. 1 and 5, the second acoustic wave filter 2 includes the second metal portion 21 provided on the third main surface 201 of the second piezoelectric substrate 20. In plan view in the thickness direction D1 of the second piezoelectric substrate 20, the second metal portion 21 has a rectangular or substantially rectangular frame shape along the outer edge of the second piezoelectric substrate 20. As illustrated in FIG. 5, in plan view in the thickness direction D1 of the first piezoelectric substrate 10, the second metal portion 21 surrounds the plurality of second functional electrodes 22, the plurality of second reflectors 23, and the plurality of wiring conductor portions. The 16th to 18th wiring conductor portions W16 to W18 of the 11th to 18th wiring conductor portions W11 to W18 of the plurality of wiring conductor portions are connected to the second metal portion 21. In plan view in the thickness direction D1 of the first piezoelectric substrate 10, the second metal portion 21 overlaps the first metal portion 11 of the first acoustic wave filter 1.

### (2.2.3) Spacer Portion

As illustrated in FIGS. 1 and 7, the spacer portion 4 is interposed between the first acoustic wave filter 1 and the second acoustic wave filter 2 in the thickness direction D1 of the first piezoelectric substrate 10. More specifically, the spacer portion 4 is interposed between the first metal portion 11 of the first acoustic wave filter 1 and the second metal portion 21 of the second acoustic wave filter 2. The spacer portion 4 has a rectangular or substantially rectangular frame shape. The material of the spacer portion 4 includes at least one of, for example, a metal and solder. In the acoustic wave device 100, the first metal portion 11 of the first acoustic wave filter 1 and the second metal portion 21 of the second acoustic wave filter 2 are joined to each other via the spacer portion 4. In other words, in the acoustic wave device 100, the spacer portion 4 defines and functions as a joint portion that joins the first acoustic wave filter 1 and the second acoustic wave filter 2 to each other. In the acoustic wave device 100, the second metal portion 21 is electrically connected to the first metal portion 11. In the acoustic wave device 100, the first metal portion 11 and the second metal portion 21 may also be directly joined to each other without the spacer portion 4.

### (2.2.4) First Conductor Portion and Third Conductor Portion

The first conductor portion 3 (see FIGS. 1 and 5) and the third conductor portion 9 (see FIG. 5) are interposed between the first acoustic wave filter 1 and the second acoustic wave filter 2 in the thickness direction D1 of the first piezoelectric substrate 10. The first conductor portion 3 and the third conductor portion 9 have conductivity.

In plan view in the thickness direction D1 of the first piezoelectric substrate 10, the first conductor portion 3 overlaps the relay electrode 8 of the first acoustic wave filter 1. In plan view in the thickness direction D1 of the first piezoelectric substrate 10, the first conductor portion 3 overlaps the second functional conductor portion E2 of the second acoustic wave filter 2. The first conductor portion 3 is interposed between the second functional conductor portion E2 of the second acoustic wave filter 2 and the relay electrode 8 of the first acoustic wave filter 1. Accordingly, in the acoustic wave device 100, the second functional conductor portion E2 of the second acoustic wave filter 2 and the relay electrode 8 are connected to each other via the first conductor portion 3. As a result, in the acoustic wave device 100, the series arm resonator S24 (see FIG. 5) of the second acoustic wave filter 2 is electrically connected to the second signal electrode 17 (see FIGS. 1 and 3) via the second functional conductor portion E2 (15th wiring conductor portion W15), the first conductor portion 3, the relay electrode 8, and the third through-via conductor V3.

In plan view in the thickness direction D1 of the first piezoelectric substrate 10, the third conductor portion 9 (see FIG. 5) overlaps the seventh wiring conductor portion W7 (see FIG. 4) and the first through-via conductor V1 (see FIG. 4) of the first acoustic wave filter 1. In addition, in plan view in the thickness direction D1 of the first piezoelectric substrate 10, the third conductor portion 9 overlaps the 11th wiring conductor portion W11 (see FIG. 5) of the second acoustic wave filter 2. The third conductor portion 9 is interposed between the 11th wiring conductor portion W11 of the second acoustic wave filter 2 and the seventh wiring conductor portion W7 of the first acoustic wave filter 1. Accordingly, in the acoustic wave device 100, the series arm resonator S21 (see FIG. 5) of the second acoustic wave filter 2 and the first through-via conductor V1 (see FIG. 4) are connected to each other via the 11th wiring conductor portion W11, the third conductor portion 9, and the seventh wiring conductor portion W7. As a result, in the acoustic wave device 100, the series arm resonator S21 of the second acoustic wave filter 2 is electrically connected to the common electrode 15 (see FIG. 3) via the 11th wiring conductor portion W11, the third conductor portion 9, the seventh wiring conductor portion W7, and the first through-via conductor V1.

### (3) Advantageous Effects

The acoustic wave device 100 according to example embodiment 1 includes the first acoustic wave filter 1, the second acoustic wave filter 2, and the first conductor portion 3. The first acoustic wave filter 1 includes the first piezoelectric substrate 10 and the first functional conductor portion E1. The first piezoelectric substrate 10 includes the first main surface 101 and the second main surface 102 that face away from each other. The first functional conductor portion E1 is provided on the first main surface 101 of the first piezoelectric substrate 10. The second acoustic wave filter 2 includes the second piezoelectric substrate 20 and the second functional conductor portion E2. The second functional conductor portion E2 is provided on the second piezoelectric substrate 20. The second acoustic wave filter 2 is provided above the first acoustic wave filter 1. The first conductor portion 3 is interposed between the first acoustic wave filter 1 and the second acoustic wave filter 2. The first conductor portion 3 is connected to the second functional conductor portion E2. The first acoustic wave filter 1 further includes the signal electrode 17, the ground electrode 18, and the second conductor portions 7. The signal electrode 17 is provided on the second main surface 102 of the first piezoelectric substrate 10. The signal electrode 17 is connected to the first conductor portion 3. The ground electrode 18 is provided on the second main surface 102 of the first piezoelectric substrate 10. The second conductor portions 7 are connected to the ground electrode 18. The ground electrode 18 overlaps the first functional conductor portion E1 and does not overlap the signal electrode 17 in plan view in the thickness direction D1 of the first piezoelectric substrate 10.

The second conductor portions 7 are provided between the first main surface 101 and the second main surface 102 of the first piezoelectric substrate 10 and is spaced apart from the first main surface 101.

In the acoustic wave device 100 according to example embodiment 1, isolation characteristics can be improved while low profile is achieved. More specifically, in the acoustic wave device 100 according to example embodiment 1, the ground electrode 18 provided on the second main surface 102 of the first piezoelectric substrate 10 overlaps the first functional conductor portion E1 and does not overlap the signal electrode 17 in plan view in the thickness direction D1 of the first piezoelectric substrate 10. As a result, in the acoustic wave device 100 according to example embodiment 1, low profile can be achieved. In addition, in the acoustic wave device 100 according to example embodiment 1, the first acoustic wave filter 1 includes the second conductor portions 7 connected to the ground electrode 18, and the second conductor portions 7 are provided between the first main surface 101 and the second main surface 102 of the first piezoelectric substrate 10 and is spaced apart from the first main surface 101. As a result, in the acoustic wave device 100 according to example embodiment 1, first parasitic capacitance is formed between the first functional conductor portion E1 and the second conductor portions 7, second parasitic capacitance is formed between the second conductor portions 7 and the signal electrode 17, and the first parasitic capacitance and the second parasitic capacitance are connected to each other in series. As a result, in the acoustic wave device 100 according to example embodiment 1, the capacitance value of parasitic capacitance between the first functional conductor portion E1 and the signal electrode 17 can be reduced, and isolation between the first functional conductor portion E1 of the first acoustic wave filter 1 and the signal electrode 17 connected to the second acoustic wave filter 2 can be improved. As a result, in the acoustic wave device 100 according to example embodiment 1, the isolation characteristics can be improved. In addition, in the acoustic wave device 100 according to example embodiment 1, the filter characteristics of the first acoustic wave filter 1 and the second acoustic wave filter 2 can be improved. Here, in the acoustic wave device 100 according to example embodiment 1, the attenuation characteristics on the high-frequency side of the pass band (corresponding to, for example, the transmission band of Band25) of the first acoustic wave filter 1 can be improved. In addition, in the acoustic wave device 100 according to example embodiment 1, the attenuation characteristics on the low-frequency side of the pass band (corresponding to, for example, the reception band of Band25) of the second acoustic wave filter 2 can be improved.

In addition, in the acoustic wave device 100 according to example embodiment 1, the second conductor portions 7 overlap the functional conductor portion E1 in plan view in the thickness direction D1 of the first piezoelectric substrate 10. As a result, in the acoustic wave device 100 according to example embodiment 1, between the first functional conductor portion E1 and the signal electrode 17, parasitic capacitance between the first functional conductor portion E1 and the second conductor portions 7 is easily generated, and the capacitance value of parasitic capacitance between the first functional conductor portion E1 and the signal electrode 17 can be easily reduced.

### Example Embodiment 2

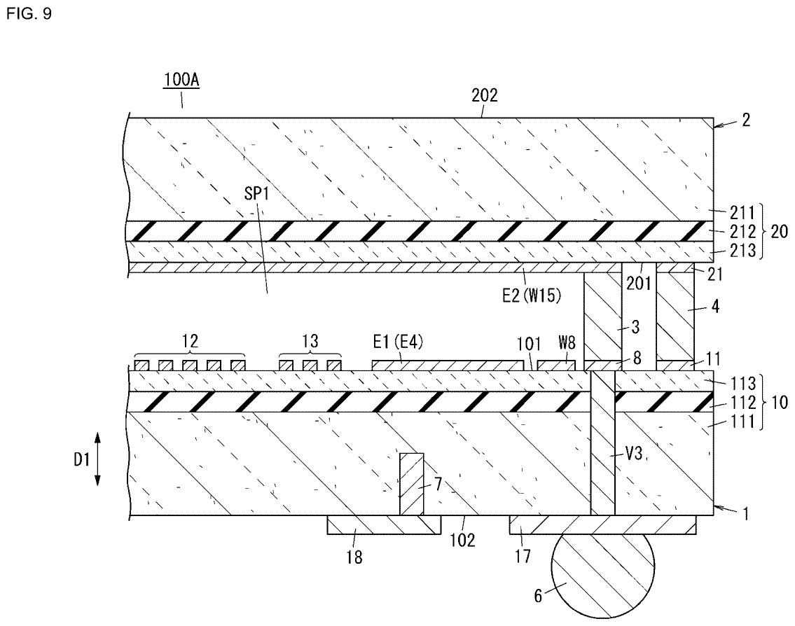

An acoustic wave device 100A according to example embodiment 2 of the present invention will be described with reference to FIG. 9. Components of the acoustic wave device 100A according to example embodiment 2 that are the same as or correspond to those of the acoustic wave device 100 (see FIG. 1) according to example embodiment 1 are denoted by the same reference numerals, and the descriptions thereof are omitted.

### (1) Structure

In the acoustic wave device 100A according to example embodiment 2, the first functional conductor portion E1 overlaps the ground electrode 18 and the signal electrode 17 in plan view in the thickness direction D1 of the first piezoelectric substrate 10. More specifically, a portion of the first functional conductor portion E1 overlaps a portion of the ground electrode 18, and another portion of the first functional conductor portion E1 overlaps a portion of the signal electrode 17.

### (2) Advantageous Effects

Since the acoustic wave device 100A according to example embodiment 2 includes the second conductor portions 7, when the first functional conductor portion E1 and the signal electrode 17 overlap each other in plan view in the thickness direction D1 of the first piezoelectric substrate 10, capacitive coupling between the first functional conductor portion E1 and the signal electrode 17 can be reduced or prevented.

### Example Embodiment 3

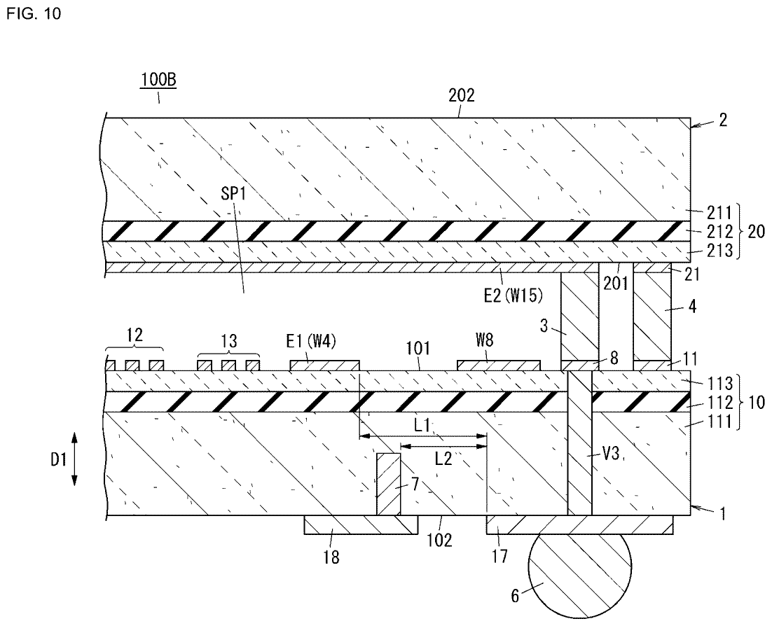

An acoustic wave device 100B according to example embodiment 3 of the present invention will be described with reference to FIG. 10. Components of the acoustic wave device 100B according to example embodiment 3 that are the same as or correspond to those of the acoustic wave device 100 (see FIG. 1) according to example embodiment 1 are denoted by the same reference numerals, and the descriptions thereof are omitted.

### (1) Structure

In the acoustic wave device 100B according to example embodiment 3, the first functional conductor portion E1 overlaps the ground electrode 18 and does not overlap the second conductor portions 7 in plan view in the thickness direction D1 of the first piezoelectric substrate 10. In the acoustic wave device 100B, in plan view in the thickness direction D1 of the first piezoelectric substrate 10, a distance L2 between the second conductor portions 7 and the signal electrode 17 is shorter than a distance L1 between the first functional conductor portion E1 and the signal electrode 17. In other words, in the acoustic wave device 100B, the first functional conductor portion E1, the second conductor portions 7, and the signal electrode 17 are provided in the order of the first functional conductor portion E1, the second conductor portions 7, and the signal electrode 17 in plan view in the thickness direction D1 of the first piezoelectric substrate 10.

### (2) Advantageous Effects

In the acoustic wave device 100B according to example embodiment 3, since the distance L2 between the second conductor portions 7 and the signal electrode 17 is shorter than the distance L1 between the first functional conductor portion E1 and the signal electrode 17 in plan view in the thickness direction D1 of the first piezoelectric substrate 10, the capacitive coupling between the first functional conductor portion E1 and the signal electrode 17 can be further reduced or prevented.

### Example Embodiment 4

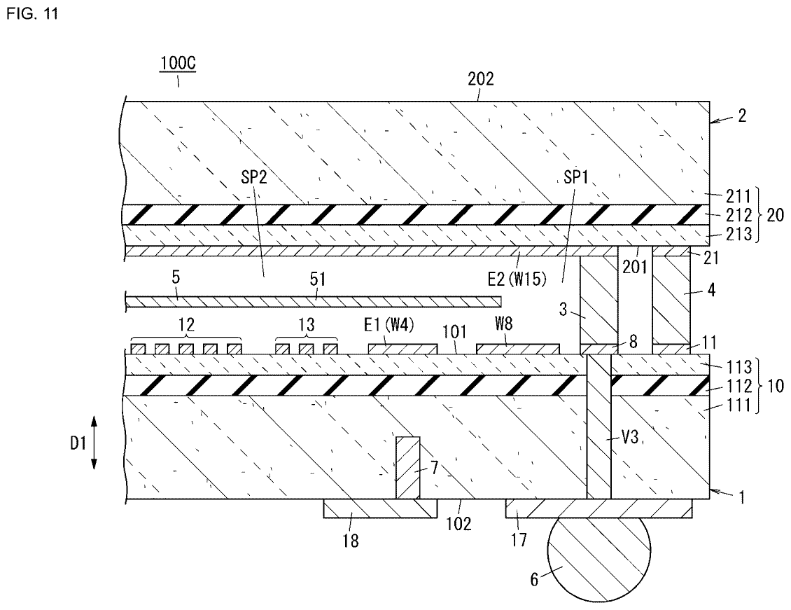

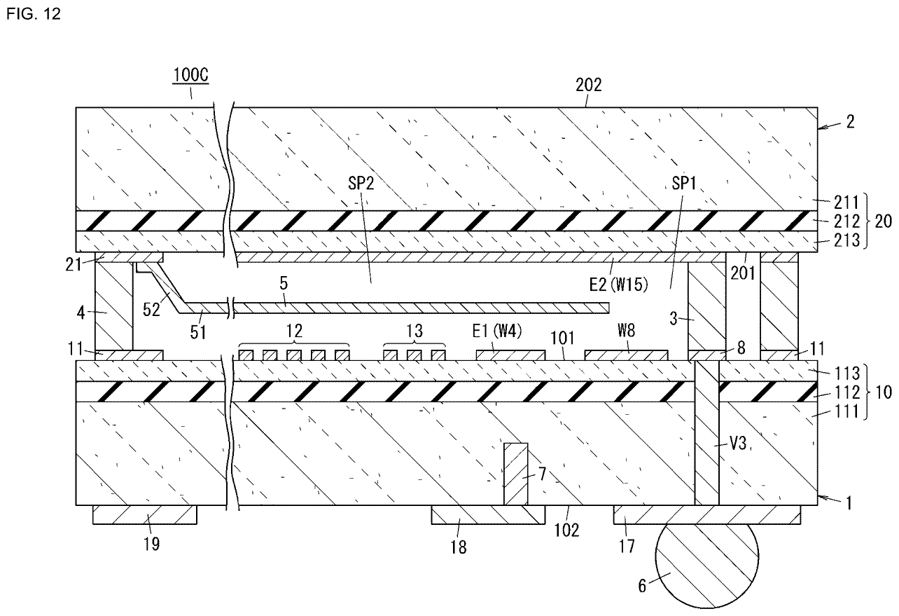

An acoustic wave device 100C according to example embodiment 4 of the present invention will be described with reference to FIGS. 11 and 12. Components of the acoustic wave device 100C according to example embodiment 4 that are the same as or correspond to those of the acoustic wave device 100 (see FIG. 1) according to example embodiment 1 are denoted by the same reference numerals and the descriptions thereof are omitted.

### (1) Structure

The acoustic wave device 100C according to example embodiment 4 differs from the acoustic wave device 100 according to example embodiment 1 in that the acoustic wave device 100C further includes a shield electrode 5.

The shield electrode 5 is provided between the first acoustic wave filter 1 and the second acoustic wave filter 2. More specifically, the shield electrode 5 is provided in the hollow space SP1 surrounded by the first piezoelectric substrate 10 of the first acoustic wave filter 1, the second piezoelectric substrate 20 of the second acoustic wave filter 2, and the spacer portion 4.

The shield electrode 5 is provided between the first functional conductor portion E1 and the second functional conductor portion E2 in the thickness direction D1 of the first piezoelectric substrate 10. The shield electrode 5 includes, for example, a first shield portion 51 that is spaced apart from the first acoustic wave filter 1 and the second acoustic wave filter 2 in the thickness direction D1 of the first piezoelectric substrate 10 and a second shield portion 52 (see FIG. 7) that connects the second acoustic wave filter 2 and the first shield portion 51 to each other. The material of the shield electrode 5 contains a metal. The acoustic wave device 100C includes a cavity SP2 formed between the shield electrode 5 and the second acoustic wave filter 2. The cavity SP2 can be formed by using, for example, a sacrificial layer etching technique. The shield electrode 5 is connected to, for example, the second metal portion 21 of the second acoustic wave filter 2. As a result, the shield electrode 5 is electrically connected to the first ground electrode 18 and the second ground electrode 19. It should be noted that the second shield portion 52 does not need to connect the second acoustic wave filter 2 and the first shield portion 51 to each other, and the second shield portion 52 may also connect the first acoustic wave filter 1 and the first shield portion 51 to each other and may also be connected to the first metal portion 11.

The first functional conductor portion E1 and the second functional conductor portion E2 overlap the shield electrode 5 in the thickness direction D1 of the first piezoelectric substrate 10. In the acoustic wave device 100C, a portion of the shield electrode 5 overlaps the entire first functional conductor portion E1 in plan view in the thickness direction D1 of the first piezoelectric substrate 10, but a portion of the shield electrode 5 may also overlap a portion of the first functional conductor portion E1. In addition, in the acoustic wave device 100C, a portion of the shield electrode 5 overlaps a portion of the second functional conductor portion E2 in plan view in the thickness direction D1 of the first piezoelectric substrate 10, but a portion of the shield electrode 5 may also overlap the entire second functional conductor portion E2.

### (2) Advantageous Effects

In the acoustic wave device 100C according to example embodiment 4, the first functional conductor portion E1 and the second functional conductor portion E2 overlap the shield electrode 5 in the thickness direction D1 of the first piezoelectric substrate 10. As a result, in the acoustic wave device 100C according to example embodiment 4, the isolation between the first functional conductor portion E1 and the second functional conductor portion E2 can be improved.

In plan view in the thickness direction D1 of the first piezoelectric substrate 10, the plurality of second conductor portions 7 may also have a shape other than a rectangle, such as a circle or a substantially circle.

In addition, the first acoustic wave filter 1 does not necessarily need to include the plurality of second conductor portions 7 and only needs to include at least one second conductor portion 7. In addition, the first acoustic wave filter 1 may also include one second conductor portion 7 surrounding the second signal electrode 17, instead of the plurality of second conductor portions 7.

In addition, when the first high-acoustic-velocity support substrate 111 is, for example, a silicon substrate as described above, the first acoustic wave filter 1 may also further include an electrically insulating film interposed between, for example, the first high-acoustic-velocity support substrate 111 and the common electrode 15, the first signal electrode 16, the second signal electrode 17, the first ground electrode 18, and the second ground electrode 19. In addition, the electrically insulating film may also be provided in a third region on the second main surface 102 of the first piezoelectric substrate 10 other than a first region that overlaps the first ground electrode 18 and a second region that overlaps the second ground electrode 19. In addition, the electrically insulating film may also be provided between first the high-acoustic-velocity support substrate 111 and each of the first through-via conductor V1, the second through-via conductor V2, the third through-via conductor V3, and the plurality of through-ground-via conductors. The material of the electrically insulating film includes, for example, silicon dioxide.

In addition, in the acoustic wave device 100, the second functional conductor portion E2 may also be provided on the fourth main surface 202 of the second piezoelectric substrate 20, instead of the third main surface 201.

In addition, the first acoustic wave filter 1 may also include a side electrode, provided across the first main surface 101, the side surface, and the second main surface 102 of the first piezoelectric substrate 10, that connects the first conductor portion 3 and the signal electrode 17 to each other, instead of the through-via conductor V3 that connects the first conductor portion 3 and the signal electrode 17 to each other.

In addition, the first piezoelectric substrate 10 is not limited to a laminated substrate including the first high-acoustic-velocity support substrate 111, the first low-acoustic-velocity film 112, and the first piezoelectric layer 113 and may also be, for example, the first piezoelectric substrate. The first piezoelectric substrate is, for example, a lithium tantalate substrate or a lithium niobate substrate.

In addition, the second piezoelectric substrate 20 is not limited to a laminated substrate including the second high-acoustic-velocity support substrate 211, the second low-acoustic-velocity film 212, and the second piezoelectric layer 213 and may also be, for example, the second piezoelectric substrate. The second piezoelectric substrate is, for example, a lithium tantalate substrate or a lithium niobate substrate.

In addition, the first piezoelectric substrate 10 may also include a first high-acoustic-velocity film interposed between the silicon substrate and the first low-acoustic-velocity film 112. In the first high-acoustic-velocity film, the acoustic velocity of a bulk wave propagating through the first high-acoustic-velocity film is higher than the acoustic velocity of an acoustic wave propagating through the first piezoelectric layer 113. In addition, the second piezoelectric substrate 20 may also include a second high-acoustic-velocity film interposed between the silicon substrate and the second low-acoustic-velocity film 212. In the second high-acoustic-velocity, the acoustic velocity of a bulk wave propagating through the second high-acoustic-velocity film is higher than the acoustic velocity of an acoustic wave propagating through the second piezoelectric layer 213. The materials of the first high-acoustic-velocity film and the second high-acoustic-velocity film are, for example, silicon nitride.

In addition, the first piezoelectric substrate 10 may also include a first close contact layer interposed between, for example, the first low-acoustic-velocity film 112 and the first piezoelectric layer 113. The first close contact layer is made of, for example, a resin (epoxy resin or polyimide resin). The second piezoelectric substrate 20 may also include a second close contact layer interposed between, for example, the second low-acoustic-velocity film 212 and the second piezoelectric layer 213. The second close contact layer is made of, for example, a resin (epoxy resin or polyimide resin). In addition, the first acoustic wave filter 1 may also further include a first protective film, provided on the first piezoelectric layer 113, that covers the plurality of first functional electrodes 12 and the plurality of first reflectors 13. The material of the first protective film is, for example, silicon dioxide. In addition, the second acoustic wave filter 2 may also further include a second protective film, provided on the second piezoelectric layer 213, that covers the plurality of second functional electrodes 22 and the plurality of second reflectors 23. The material of the second protective film is, for example, silicon dioxide.

In addition, the first acoustic wave filter 1 and the second acoustic wave filter 2 are not limited to ladder filters and may also be, for example, T-type filters.

In addition, the first acoustic wave filter 1 and the second acoustic wave filter 2 may also be acoustic wave filters that use, for example, a boundary acoustic wave, a plate wave, or the like.

In addition, the circuit structure of the acoustic wave devices 100, 100A, 100B, and 100C is not limited to the example in FIG. 8. In addition, in the acoustic wave devices 100, 100A, 100B, and 100C, the first acoustic wave filter 1 and the second acoustic wave filter 2 are not limited to a transmission filter and a reception filter, respectively, and the first acoustic wave filter 1 the second acoustic wave filter 2 may also be a reception filter and a transmission filter, respectively.

This specification discloses the following example embodiments of the present invention.

An acoustic wave device (100, 100A, 100B, 100C) according to an example embodiment includes a first acoustic wave filter (1), a second acoustic wave filter (2), and a first conductor portion (3). The first acoustic wave filter (1) includes a first piezoelectric substrate (10) and a first functional conductor portion (E1). The first piezoelectric substrate (10) includes a first main surface (101) and a second main surface (102) that face away from each other. The first functional conductor portion (E1) is provided on the first main surface (101) of the first piezoelectric substrate (10). The second acoustic wave filter (2) includes a second piezoelectric substrate (20) and a second functional conductor portion (E2). The second functional conductor portion (E2) is provided on the second piezoelectric substrate (20). The second acoustic wave filter (2) is provided above the first acoustic wave filter (1). The first conductor portion (3) is interposed between the first acoustic wave filter (1) and the second acoustic wave filter (2). The first conductor portion (3) is connected to the second functional conductor portion (E2). The first acoustic wave filter (1) includes a signal electrode (17), a ground electrode (18), and a second conductor portion (7). The signal electrode (17) is provided on the second main surface (102) of the first piezoelectric substrate (10). The signal electrode (17) is connected to the first conductor portion (3). The ground electrode (18) is provided on the second main surface (102) of the first piezoelectric substrate (10). The second conductor portion (7) is connected to the ground electrode (18). The ground electrode (18) overlaps the first functional conductor portion (E1) and does not overlap the signal electrode (17) in plan view in a thickness direction (D1) of the first piezoelectric substrate (10). The second conductor portion (7) is provided between the first main surface (101) and the second main surface (102) of the first piezoelectric substrate (10) and is spaced apart from the first main surface (101).

According to an example embodiment, it is possible to improve isolation characteristics while achieving low profile.

In an acoustic wave device (100, 100A, 100C) according to an example embodiment, the second conductor portion (7) overlaps the first functional conductor portion (E1) in plan view in the thickness direction (D1) of the first piezoelectric substrate (10) in the first aspect.

According to an example embodiment, between the first functional conductor portion (E1) and the signal electrode (17), parasitic capacitance between the first functional conductor portion (E1) and the second conductor portion (7) is easily generated, and the capacitance value of parasitic capacitance between the first functional conductor portion (E1) and the signal electrode (17) can be easily reduced.

In an acoustic wave device (100A) according to an example embodiment, the first functional conductor portion (E1) overlaps the signal electrode (17) in plan view in the thickness direction (D1) of the first piezoelectric substrate (10) in the first aspect.

According to an example embodiment, when the first functional conductor portion (E1) and the signal electrode (17) overlap each other in plan view in the thickness direction (D1) of the first piezoelectric substrate (10), capacitive coupling between the first functional conductor portion (E1) and the signal electrode (17) can be reduced or prevented.

In an acoustic wave device (100B) according to an example embodiment, a distance (L2) between the second conductor portion (7) and the signal electrode (17) is shorter than a distance (L1) between the first functional conductor portion (E1) and the signal electrode (17) in plan view in the thickness direction (D1) of the first piezoelectric substrate (10).

According to an example embodiment, capacitive coupling between the first functional conductor portion (E1) and the signal electrode (17) can be further reduced or prevented.

In an acoustic wave device (100, 100A, 100B, 100C) according to an example embodiment, the second piezoelectric substrate (20) includes a third main surface (201) and a fourth main surface (202) that face away from each other in any one of the first to fourth aspects. The third main surface (201) of the second piezoelectric substrate (20) faces the first main surface (101) of the first piezoelectric substrate (10). The second functional conductor portion (E2) is provided on the third main surface (201) of the second piezoelectric substrate (20).

According to an example embodiment, the wiring length between the second functional conductor portion (E2) and the signal electrode (17) can be reduced.

An acoustic wave device (100C) according to an example embodiment further includes a shield electrode (5). The shield electrode (5) is provided between the first acoustic wave filter (1) and the second acoustic wave filter (2). The first functional conductor portion (E1) and the second functional conductor portion (E2) overlap the shield electrode (5) in the thickness direction (D1) of the first piezoelectric substrate (10).

According to an example embodiment, isolation between the first functional conductor portion (E1) and the second functional conductor portion (E2) can be improved.

In an acoustic wave device (100C) according to an example embodiment, the first acoustic wave filter (1) further includes a second ground electrode (19) different from a first ground electrode (18) that is the ground electrode (18) in the sixth aspect. The second ground electrode (19) is provided on the second main surface (102) of the first piezoelectric substrate (10). The shield electrode (5) is electrically connected to the first ground electrode (18) and the second ground electrode (19).

According to an example embodiment, shielding performance of the shield electrode (5) can be improved.

In an acoustic wave device (100, 100A, 100B, 100C) according to an example embodiment, the first acoustic wave filter (1) further includes a through-via conductor (V3). The through-via conductor (V3) passes through the first piezoelectric substrate (10) and connects the first conductor portion (3) and the signal electrode (17) to each other.

According to an example embodiment, the wiring length between the first conductor portion (3) and the signal electrode (17) can be reduced.

In an acoustic wave device (100, 100A, 100B, 100C) according to an example embodiment, one of the first acoustic wave filter (1) and the second acoustic wave filter (2) is a transmission filter, and the other of the first acoustic wave filter (1) and the second acoustic wave filter (2) is a reception filter. The first acoustic wave filter (1) further includes a common electrode (15) provided on the second main surface (102) of the first piezoelectric substrate. The common electrode (15) is a signal input/output electrode common to the transmission filter and the reception filter.

According to an example embodiment, isolation between the transmission filter and the reception filter can be improved.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a first acoustic wave filter including a first piezoelectric substrate including a first main surface and a second main surface facing away from each other and a first functional conductor portion on the first main surface of the first piezoelectric substrate;
a second acoustic wave filter including a second piezoelectric substrate and a second functional conductor portion on the second piezoelectric substrate, the second acoustic wave filter being located above the first acoustic wave filter; and
a first conductor portion interposed between the first acoustic wave filter and the second acoustic wave filter and connected to the second functional conductor portion; wherein
the first acoustic wave filter includes a signal electrode on the second main surface of the first piezoelectric substrate and connected to the first conductor portion, a ground electrode on the second main surface of the first piezoelectric substrate, and a second conductor portion connected to the ground electrode;
the ground electrode overlaps the first functional conductor portion and does not overlap the signal electrode in plan view in a thickness direction of the first piezoelectric substrate; and
the second conductor portion is located between the first main surface and the second main surface of the first piezoelectric substrate and spaced apart from the first main surface.

2. The acoustic wave device according to claim 1, wherein the second conductor portion overlaps the first functional conductor portion in plan view in the thickness direction of the first piezoelectric substrate.

3. The acoustic wave device according to claim 1, wherein the first functional conductor portion overlaps the signal electrode in plan view in the thickness direction of the first piezoelectric substrate.

4. The acoustic wave device according to claim 1, wherein a distance between the second conductor portion and the signal electrode is shorter than a distance between the first functional conductor portion and the signal electrode in plan view in the thickness direction of the first piezoelectric substrate.

5. The acoustic wave device according to claim 1, wherein
the second piezoelectric substrate includes a third main surface and a fourth main surface facing away from each other;
the third main surface of the second piezoelectric substrate faces the first main surface of the first piezoelectric substrate; and
the second functional conductor portion is located on the third main surface of the second piezoelectric substrate.

6. The acoustic wave device according to claim 5, further comprising:
a shield electrode between the first acoustic wave filter and the second acoustic wave filter; wherein
the first functional conductor portion and the second functional conductor portion overlap the shield electrode in the thickness direction of the first piezoelectric substrate.

7. The acoustic wave device according to claim 6, wherein
the first acoustic wave filter further includes a second ground electrode different from a first ground electrode defining the ground electrode;
the second ground electrode is provided on the second main surface of the first piezoelectric substrate; and
the shield electrode is electrically connected to the first ground electrode and the second ground electrode.

8. The acoustic wave device according to claim 1, wherein the first acoustic wave filter further includes a through-via conductor passing through the first piezoelectric substrate and connecting the first conductor portion and the signal electrode to each other.

9. The acoustic wave device according to claim 1, wherein
one of the first acoustic wave filter and the second acoustic wave filter is a transmission filter, and another of the first acoustic wave filter and the second acoustic wave filter is a reception filter;
the first acoustic wave filter further includes a common electrode on the second main surface of the first piezoelectric substrate; and
the common electrode is a signal input/output electrode common to the transmission filter and the reception filter.

10. The acoustic wave device according to claim 1, wherein a thickness of the first piezoelectric substrate is about 50 μm or greater and about 200 μm or smaller.

11. The acoustic wave device according to claim 1, wherein the first piezoelectric substrate includes a first high-acoustic-velocity support substrate, a first low-acoustic-velocity film on the first high-acoustic-velocity support substrate, and a first piezoelectric layer on the first low-acoustic-velocity film.

12. The acoustic wave device according to claim 11, wherein the first piezoelectric layer includes lithium tantalate or lithium niobate.

13. The acoustic wave device according to claim 11, wherein the high-acoustic-velocity support substrate includes a silicon substrate.

14. The acoustic wave device according to claim 13, wherein a thickness of the silicon substrate is about 10 λ or greater and about 180 μm or smaller, where λ is a wavelength of an acoustic wave determined by an electrode finger pitch of an IDT electrode included in the first functional conductor portion.

15. The acoustic wave device according to claim 13, wherein a resistivity of the silicon substrate is about 1 kΩcm or higher.

16. The acoustic wave device according to claim 13, wherein a resistivity of the silicon substrate is about 2 kΩcm or higher.

17. The acoustic wave device according to claim 13, wherein a resistivity of the silicon substrate is about 4 kΩcm or higher.

18. The acoustic wave device according to claim 1, wherein the first low-acoustic-velocity film includes silicon dioxide.

19. The acoustic wave device according to claim 19, wherein a thickness of the first low-acoustic-velocity film is about 2 λ or smaller.
